(19) United States
(12) Patent Application Publication
(10) Pub. No.: US 2026/0291510 A1
(43) Pub. Date: Sep. 24, 2026

(54) CLOCK GENERATION APPARATUSES AND METHODS

(71) Applicant: Intel Corporation, Santa Clara, CA (US)

(72) Inventors: Kuan-Yueh SHEN, Portland, OR (US); Bennett YOUNG, Hillsboro, OR (US); Nasser A. KURD, Portland, OR (US); Qi WANG, Portland, OR (US); Praveen MOSALIKANTI, Portland, OR (US); Vaughn GROSSNICKLE, Beaverton, OR (US)

(21) Appl. No.: 19/088,682

(22) Filed: Mar. 24, 2025

(51) Int. Cl. H03L 7/197; H03L 7/089; H03L 7/091

(52) U.S. Cl. CPC H03L 7/1976; H03L 7/0891; H03L 7/091

(57) ABSTRACT

Clock generation circuits with FLL and/or PLL circuits to limit frequency overshoot and/or facilitate efficient FLL and PLL performance using fewer circuit resources.

### BACKGROUND

FLL (frequency lock loop) and PLL (phase lock loop) circuits are commonly used to generate stable and accurate clock sources for a variety of different applications including interconnect fabric and core clock generation. With such applications, dynamic voltage/frequency scaling (DVFS or DFS) is used to quickly change operating frequencies to respond to changes in workload and power management demands. In order to efficiently implement such DFS techniques, it is desirable to be able to change clocks on-the-fly without having to halt or reset the circuit blocks being clocked. To be able to do this effectively, it would be desirable to be able to do this without incurring excessive, if any, frequency overshoot when a PLL and/or FLL circuit frequency is being upwardly adjusted so as to avoid issues that can arise when frequencies go above levels that can be supported by currently programmed operational supply voltages.

FLLs are less costly to implement, but they can be limited in their ability to provide frequencies other than integer multiples of an applied reference input frequency. In addition, their output frequencies can deviate from their target frequencies by more than several tenths of ppm (parts-per-million).

PLLs such as low-jitter PLLs can generate accurate clock outputs with very little frequency error, and they can be configured as fractional divide ratio PLLs such that they can generate output frequencies not restricted to integer multiples of their reference clocks. However, when their frequencies are to increase, they have difficulty achieving on-the-fly frequency changes without problematically overshooting their target frequencies, e.g., up to 30 MHz, due to the discrete nature of their feedback divide ratios. (With PLLs and FLLs, divide ratio refers to a division value used in a feedback path of the PLL or FLL that is used to adjust their output clock frequencies. They are controlled such that the output clock frequency typically corresponds to the divide ratio multiplied by the PLL/FLL input reference clock frequency. For example, if the ratio is 17 with a 100 MHz reference clock, the frequency transition should eventually settle to 1.7 GHz. Accordingly, “ratio” and “frequency” are commonly used interchangeably when referring to PLL and/or FLL operation. That is, an increase in PLL/FLL ratio typically results in an increase in PLL/FLL clock frequency. Along these lines, a fractional divide ratio, ratios that can be integer or non-integer values, may be used to generate clock frequencies that aren't limited to integer multiples of reference clock frequencies.)

Accordingly, it would be desirable to have improved FLL and/or PLL solutions. For example, in some applications, it would be desirable to have a PLL that can provide dynamic frequency scaling (DFS) changes without problematically over-shooting a target frequency. In some embodiments, it would also be desirable to have more efficiently implementable FLL and/or PLL designs that can provide adequate performance without consuming excessive circuit resources.

### BRIEF DESCRIPTION OF THE DRAWINGS

The disclosure may best be understood by referring to the following description and accompanying drawings that are used to illustrate embodiments. In the drawings:

FIG. 1 is a diagram of a conventional charge pump based PLL that may be used with a ratio step control circuit in accordance with some embodiments.

FIG. 2 is a diagram showing a fractional-N PLL with QEC including a ratio step control circuit 200 in accordance with some embodiments.

FIG. 3 is a flow diagram showing a routine for implementing a frequency operating point increase using a step control circuit in accordance with some embodiments.

FIG. 4 is a graph showing phase error and divide ratios over time for an exemplary simulated system.

FIG. 5 is a conceptual diagram of a hybrid FLL-PLL architecture in accordance with some embodiments.

FIG. 6A is a diagram of a hybrid FLL-PLL circuit in accordance with some embodiments.

FIG. 6B is a diagram of a charge pump reference-current generation circuit in accordance with some embodiments.

FIG. 7 illustrates an example computing system including ??? in accordance with some embodiments.

FIG. 8 illustrates a block diagram of an example processor that may have one or more cores and an integrated memory controller in accordance with some embodiments.

FIG. 9 is a block diagram illustrating a parallel processing computing system configured to implement one or more aspects of the examples described herein.

### DETAILED DESCRIPTION

In some embodiments, a PLL circuit with the ability to carry out dynamic frequency scaling (DFS) with substantially little, if any, overshoot may be provided. In some embodiments, this may be achieved using a fractional sigma-delta PLL with QEC (quantization error correction) in concert with a ratio step control circuit. The sigma-delta based PLL with QEC can function at relatively high bandwidths while delivering matched phase and periodic jitter.

In some embodiments, to increase PLL frequency (e.g., increasing ratio) a ratio step control circuit may adjust an applied divide ratio to change using step sizes that are based on current (present) PLL phase error (PE). In some embodiments, the steps may also, or alternatively, be based on a ratio error, a difference between the current ratio step and the target ratio.

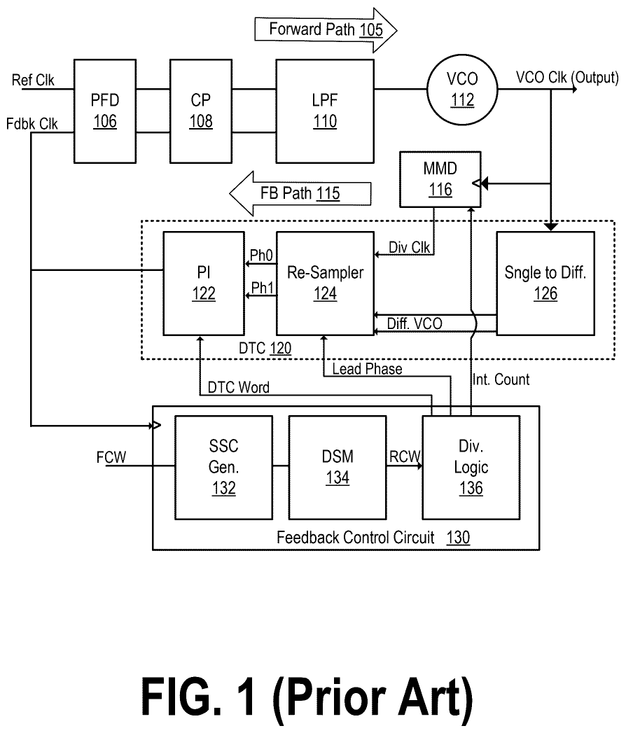

FIG. 1 is a block diagram of a conventional charge pump based PLL that may be used with a ratio step control circuit in accordance with some embodiments. The PLL is a fractional-N (or simply fractional) PLL with quantization error correction (QEC). It generally includes a forward path 105, a feedback path 115 and a feedback control circuit 130, coupled together as shown. The forward path includes a phase frequency detector (PFD) 106, charge pump 108, low pass filter (LPF) 110, and voltage controlled oscillator (VCO) 112, coupled together to generate a PLL output clock (VCO Clk) based on an input reference clock (Ref Clk). Operation of a forward path 105 is well known and thus will not be discussed in detail. However, it should be appreciated that there are many different ways to implement the circuits in the forward path, depending on design considerations, and the embodiments are not limited to the example depicted in FIG. 1.

The feedback path 115 is coupled between the PLL output at one end and a feedback clock input (Fdbk Clk) to the forward path at another end. The feedback path 115 includes a fractional divider circuit (multi-modulus divider, MMD, in this example) 116 coupled to a digital to time converter (DTC) circuit 120, which, among other things, may be used to provide quantization error correction (QEC) to compensate for phase error introduced by the fractional divider circuit 116.

The DTC circuit 120, in some embodiments, includes a phase interpolator circuit 122, a re-sampler circuit 124, and a single-ended to differential conversion circuit 126, coupled together as shown.

The feedback control circuit 130 is coupled to the feedback path 115, as well as to the forward path 105 at the PLL's Ref Clk input. The feedback control circuit 130 includes a spread spectrum clock (SSC) generation circuit 132, a delta-sigma modulation (DSM) circuit 134, and divide (or ratio) control logic 136, coupled together as shown.

The divider circuit 116, which in this example is implemented with a multi mode divider (MMD) is adjustable to control the PLL through the VCO to generate a desired clock frequency that corresponds to the divider ratio multiplied by the frequency of the input reference clock (Ref Clk). The fractional divider may achieve the different, non-integer frequency values in any suitable manner. For example, the depicted MMD circuit includes a counter that may use weighted time-averaging of two or more different integer count values to achieve a desired integer or non-integer divide-by ratio. With the depicted fractional divider, a precise divide-ratio resolution, e.g., 1/[2 m] (where m denotes the number of floating-point bits in the divider) may be attained. However, with the use of such a fractional divider, quantization phase error is introduced. Fortunately, this phase error is deterministic and thus can be compensated for in real time using the DTC circuit 120. This use of a DTC is sometimes referred to as quantization error correction (QEC).

With the depicted example, QEC is implemented with the DTC 120 disposed within the feedback path with the divider circuit 116. The single-ended to differential (S2D) circuit 126 receives the VCO Clk signal and converts it to a corresponding differential signal (Diff. VCO) that includes complimentary VCO clock components provided to the re-sampler circuit 124. The re-sampler circuit 124 retimes an output (Div Clk) from the divider circuit 116 using the complementary differential clock components from the S2D circuit 126. The re-sampler circuit 124 generates a first (Ph0) signal and a second (Ph1) signal. In some embodiments, the Ph0 signal is controlled to be at some suitable, consistent delayed version of the Div Clk output, while the Ph1 signal is controlled to mirror Ph0 but delayed by one-half of a VCO Clk cycle.

The phase interpolator (PI) 122 interpolates the PH0 and PH1 signals by a controllable amount to essentially provide the Div Clk signal but with a suitable fractional delay of a VCO cycle for each sampling cycle so that the phase error between the reference clock (Ref Clk) and the feedback clock (Fdbk Clk) approaches zero to remove the phase error as a result of the fractional-N quantization error.

The feedback control circuit 130 receives at an input a digital frequency control word (FCW) signal that corresponds to the target clock frequency that is to be generated by the PLL at its output. With this example, which includes spread spectrum generation (SSC) and delta-sigma modulation functionality, the FCW signal is fed into, and processed through, the SSC generation 132 and DSM 134 circuits, which produce an appropriate time-varying, ratio control word (RCW) that is provided to the divider logic 136. The divider logic 136, in turn, generates an integer count (Int Count) value for the divider 116 to achieve the desired fractional-N output ratio, which translates to the desired PLL output frequency. It also generates appropriate control signals (Lead Phase, DTC Word) for the re-sampler and PI circuits, respectively, to implement the QEC based on the currently applied divide ratio. (It should be appreciated that the logical circuit blocks of the feedback control circuit 130, as with other logical control circuits in this disclosure, may be implemented with any suitable combination of hardware and software components. For example, it may use controllers, e.g., formed from a micro-controller running code and/or a finite state machine (FSM), along with other discrete circuit components, analog and/or digital, to carry out control operations as described herein.

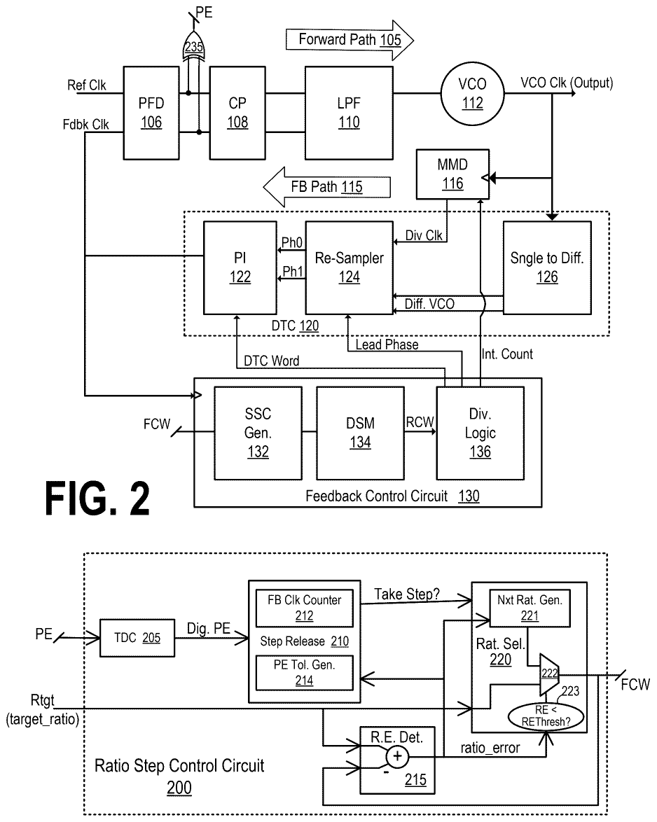

FIG. 2 is a block diagram showing a fractional-N PLL with QEC including a ratio step control circuit 200 in accordance with some embodiments. With the architecture of a delta-sigma fractional PLL including QEC and relatively wide PLL bandwidth (e.g., tens or more MHz), the ratio step control circuit can facilitate DFS with little, if no, overshoot when increasing PLL frequency. In some embodiments, it operates to control ratio step sizes and the time when ratio step transitions can occur based on the difference between the current ratio (or frequency) and the target ratio (or frequency). It may also control these parameters based on whether the PLL phase error (PE) is within a tolerance, which in some embodiments, may decrease as the ratio gets closer to the target. With such approaches, overshoot-free DFS transitions can occur even with wide-bandwidth charge pump PLLs. In fact, in some embodiments, throughout a DFS transition process, the PLL may even maintain its charge pump strength configuration.

With the depicted example, the ratio step control (or simply ratio control) circuit 200 includes a time-to-digital (TDC) converter 205, a step release circuit 210, a ratio error detection circuit 215, and a ratio selection circuit 220, coupled together as shown. (Note that the ratio control circuit may also be referred to as a frequency control circuit with its constituent logical units operating in terms of frequency and/or ratio controls since as described above, a PLL frequency is typically controlled by controlling a PLL feedback divider ratio. Specific implementations will depend on how PLL frequency is controlled for a PLL that is to be controlled with the techniques described herein.)

The ratio step control circuit 200 receives a phase error (PE) signal from the PLL and a ratio target (Rtgt) signal from a clock generator control agent (e.g., as part of a dynamic voltage-frequency scaling controller). It also has an output (FCW) that is coupled with the PLL to provide it with a frequency control word for setting the PLL frequency through a ratio setting, with this implementation.

Note that the step control circuit 200 may be clocked using any suitable clock source. With the depicted example, the step control circuit 200 is clocked using the Fdbk Clk from the PLL instead, for example, of using another clock such as the Ref Clk. When the divider ratio is increased rapidly, the Fdbk Clk can slow down relative to the Ref Clk. Since the divider ratio is captured by the MMD in the feedback path, clocking the step control circuitry using the Ref Clk could result in multiple incorrect ratio steps before the ratio change updates, introducing redundant phase error. Accordingly, in some embodiments, a clock from the feedback path may be used to avoid such issues.

The TDC circuit 205, at an input, is coupled to the PLL to receive a phase error (PE) signal that corresponds to the real-time phase error of the PLL. With this embodiment, the PE signal is derived from an output of an XOR circuit 235 that is coupled to output components (e.g., up, down) from the PLL PFD 106. From here, the TDC circuit 205 generates a digitized version (Dig. PE) of the PE signal and provides it to the step release circuit 210. In some embodiments, the TDC may have a resolution of 50 pS, depending on the operating parameters of the other circuit blocks.

The step release circuit 210 includes a feedback clock counter 212 and a PE tolerance generator 214. The step release circuit 210, along with the ratio select circuit 220, are coupled to the ratio error detection circuit 215 to receive therefrom a ratio error value, which is the difference between the target ratio and the currently applied ratio. The ratio error detection circuit 215 includes suitable logic for efficiently determining the difference between the current ratio and the target ratio.

The feedback clock counter 212 counts the number of feedback clock (Fdbk Clk) cycles that have occurred since the last ratio step towards the target ratio was made. The PE tolerance (or simply tolerance) generator 214 defines (e.g., calculates or retrieves) a tolerance threshold for the PE level to control when the next ratio step can take place. In some embodiments, it determines if the phase error (PE) is less than the tolerance threshold for a number of (e.g., two) consecutive measurement cycles. In response to the PE being below the tolerance threshold for a sufficient number of cycles (e.g., 1 or more), the step release circuit 210 causes a signal (Take Step?) to assert, informing the ratio select circuit 220 to control the PLL to go to the next ratio value.

In some embodiments, the tolerance threshold changes with the ratio error, e.g., it decreases over time as the current ratio gets increasingly closer to the target ratio. For example, with some embodiments, the tolerance is based on a logarithmic (e.g., base 2 log function) of the ratio error.

Among other things, the feedback clock count may be used to inform the tolerance threshold value, or it may be used to apply a delay limit (e.g., min or max) between ratio transitions.

The ratio select circuit 220 includes a next ratio generator (Nxt Ratio Gen) 221, a multiplexer switch 222, and a comparator 223. In some embodiments, the next ratio generator defines the next ratio value based on the current ratio+the ratio error (target ratio-current ratio) multiplied by a gain (k). The gain may be any suitable value and may be static or dynamic, depending on design considerations. In some embodiments, the gain may be a scalar value that represents the gain of proportional control, corresponding to the proportion of remaining ratio error that is traversed for each frequency step. The gain may be logically determined from the ratio error. For example, if the ratio error is large, the gain should be lower to limit unpredictable overshoot from nonlinear PLL operation. Once the ratio error is smaller and the PLL is operating in a suitably linear regime, the gain can increase. In some embodiments, gain (k) values using binary word shift and additions (e.g., 0.375, 0.5, 0.625, etc.) may be used, as they are relatively convenient to implement.

The multiplexer switch 222 selects either the next ratio from next ratio generator 221 or the target ratio itself, depending on how close the current ratio is to the target ratio. It provides the selected ratio (next or Rtgt) at an output, of the step control circuit 200, that is coupled to the FCW (frequency control word) input of the PLL. At comparator 223, if the ratio error is less than a ratio error threshold, the comparator asserts, selecting the target ratio (Rtgt) at multiplexer switch 222. Otherwise, it selects the next ratio from next ratio generator 221 to provide it to the PLL's FCW input.

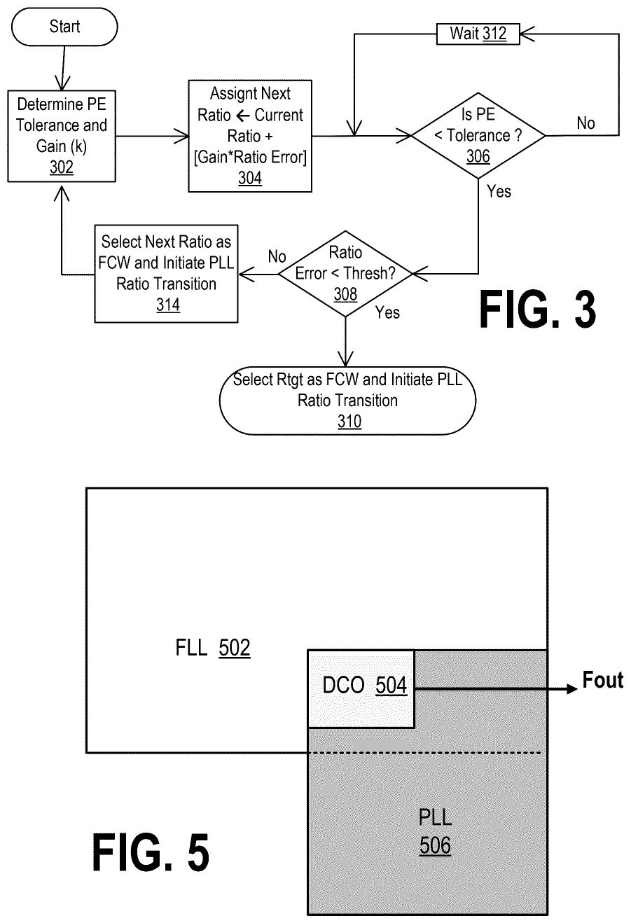

FIG. 3 is a flow diagram showing a routine for implementing a frequency operating point increase using a step control circuit in accordance with some embodiments. (Note that this routine assumes that the supply voltage for the PLL an; /or other clock distribution circuitry has reached its target level associated with the target frequency. Depending on V/F operating points and tolerances, a frequency adjustment to a higher frequency typically should not initiate until a supply voltage adjustment has completed. Likewise, PLL/clock distribution supply voltages should not decrease until a downward frequency adjustment has completed.)

For a frequency increase, the routine begins at 302 and determines a PE tolerance and gain parameter (e.g., k) for a next ratio step. At 304, it sets the next ratio value to be the current ratio plus the gain multiplied by the ratio error.

From here, it proceeds to 306 and determines if the phase error (PE) is less than the PE tolerance. This prevents the currently applied PLL ratio from updating until the PLL phase error is sufficiently small. For example, it may require the PE to remain below the tolerance limit for two or more consecutive measurement cycles before it allows the applied PLL ratio to increase so as to avoid incurring significant frequency spikes.

At 306, if the PE is less than the PE tolerance, then the routine goes to 308 and determines if the ratio error is less than the ratio error threshold. For example, in some embodiments, this corresponds to the comparator check at 223 from FIG. 2. If the ratio error is less than the threshold, then the routine goes to 310 and selects Rtgt as the frequency control word (FCW) for the PLL and Initiates a PLL ratio transition. On the other hand, at 308, if the ratio error was not less than the ratio error threshold, then it proceeds to 314 and selects the previously determined next ratio as the frequency control word for the PLL and Initiates the PLL ratio transition. From here, it goes to 302 and proceeds as described.

Returning back to the determination at 306, if the phase error (PE) was not less than the PE tolerance, then the routine would go to 312 and wait, or otherwise loop upon itself, until the PE is less than the PE tolerance at 306 when it can initiate a frequency step transition. (Note that this flow example should not be construed to be limited to the specific order in which the actions are shown. For example, while the PE tolerance check at 306 is shown to take place before the ratio selection at 308, these determinations could be reversed, with the ratio step size being selected, and ready for a transition when the PE tolerance is assessed for determining when the ratio (frequency) step transition can occur.)

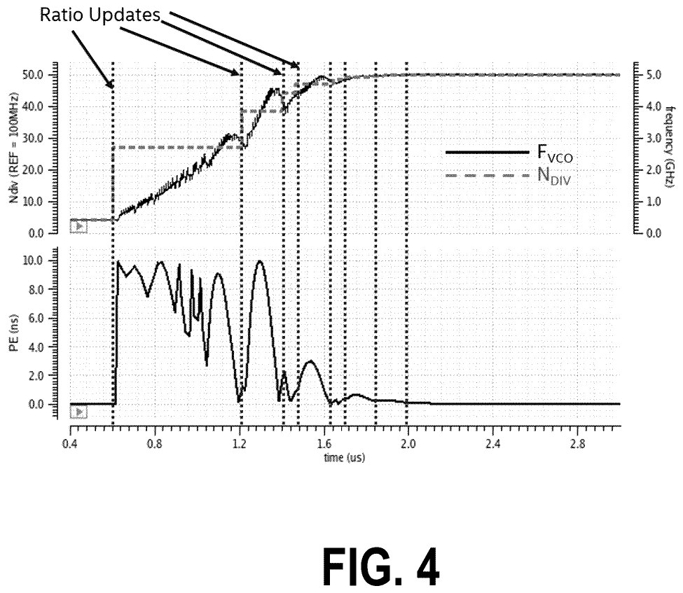

FIG. 4 is a graph showing phase error and divide ratios over time for an exemplary simulated system. This exemplary system has a dynamically adjustable frequency ranging from 400 MHz to 5.0 GHz (ratio values of 4 to 50 with a 100 MHz reference clock). With a large starting ratio error, it can be seen that the gain begins at 0.375. Once the ratio error shrinks significantly and the frequency vs. time becomes more linear, the Gain increases to 0.5. In this example, the gain is 0.5 throughout the frequency transition process. It can be observed that the overshoot above the target frequency of 5 GHz is minimal, if not nonexistent. This method of calculating the next divide ratio is used as an example, any number of different methods could be used in the overshoot-free DFS process. As the ratio error decreases, so does the phase error Tolerance, decreasing the phase error until the final ratio transition step to a target frequency.

### Hybrid PLL-FLL

Frequency lock loop (FLL) circuits can be useful clock generation sources as they can provide fast frequency transitions without excessive frequency overshoot. Also, they enable the integration of features such as seamless adaptive clocking. Unfortunately, they also typically experience phase jitter and frequency inaccuracies (e.g., up to several hundreds of ppm). These weaknesses have limited FLL applications such as for input/output (IO) blocks, display engines, and synchronous clock domain crossings, e.g., between a Double Data Rate (DDR) PHY and a memory controller. Moreover, without an accompanying PLL, they typically cannot provide sufficient phase accuracy to facilitate high volume manufacturing (HVM) testing.

On the other hand, simply replacing a FLL with a PLL has its drawbacks as well. PLLs typically consume greater circuit resources than FLLs, and replacing a FLL with a PLL would give up the favorable aspects of FLLs as described above. Accordingly new approaches would be desired.

In some embodiments, a hybrid PLL-FLL architecture is provided that retains beneficial aspects of both FLLs and PLLs. For example, with some implementations, a hybrid architecture can result in low jitter with a unified, hybrid FLL-PLL clock path, achieving fast lock, negligible overshoot frequency transitions, and little, if any, frequency error while not consuming excessive area.

FIG. 5 is a conceptual diagram of a hybrid FLL-PLL architecture in accordance with some embodiments. The hybrid architecture combines FLL components 502 with PLL components 506 that share certain common components 504. With the depicted example, a PLL is configured to share the FLL's digitally controlled oscillator (DCO) 504 and output clock path. In some embodiments, the FLL is initially activated to lock to a target frequency. The PLL can then take over DCO control once it has frequency locked at the target. The PLL is then responsible for reducing the output phase jitter and maintaining the reduced jitter output.

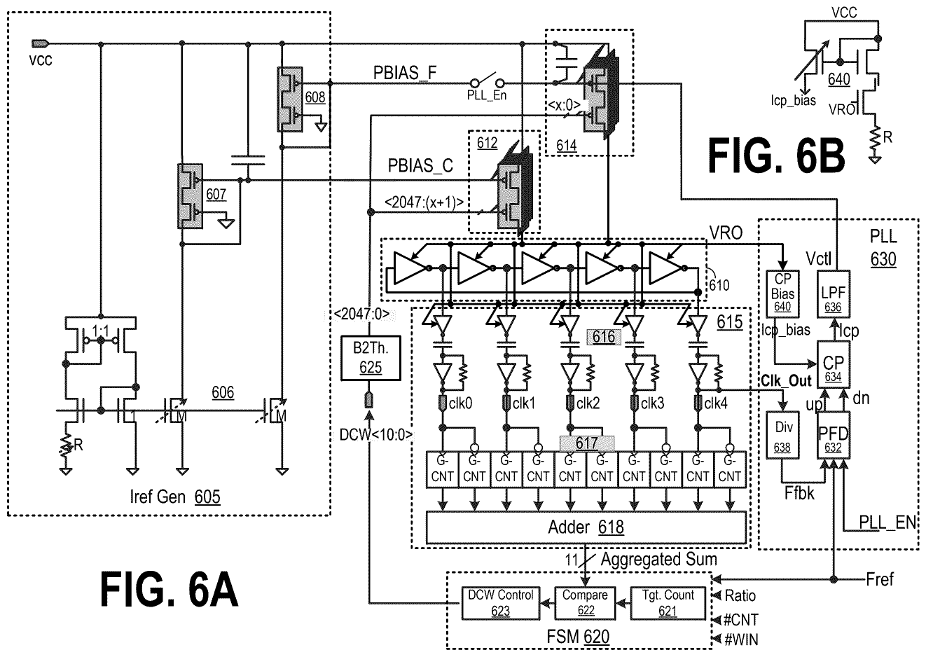

FIG. 6A is a block diagram of a hybrid FLL-PLL circuit in accordance with some embodiments. With this example, PLL components 630, without a separate, dedicated controllable oscillator, are incorporated into a FLL circuit that includes a controllable oscillator to be shared by the FLL and PLL components.

The FLL components include a current reference (Iref) generation circuit 606, a digitally controllable oscillator (DC)) 610, a course-tune, current-mode digital-to-analog (DAC) circuit 612, a fine-tune, current mode DAC 614, frequency count circuit 615, finite state machine (FSM) circuit 620, and a binary-to-Thermometer (B2Th) encoder 625, coupled together as shown. There is also a switch (PLL-En) for switching oscillator control between the FLL and PLL portions.

The DCO 610 is formed using a current-starved multi-stage (five stages in this example) ring oscillator (RO). The RO is driven by the course and fine tune current-mode DACs 612, 614, respectively. The DACs are controlled through the B2Th encoder 625 by a DCO control word (DCW) from the FSM 620. The thermometer coded word (2048 bits in this example) is divided into a course component made of the most significant bits (<2047:(x+1)) for the course DAC 612 and a fine component made from the least significant bits (<x:0) for the fine-tune DAC 614. The DACs convert their DCO input word components into a number of active PMOS current sources, up to a total of 2048 in total, considering both DACs.

The DACs, 612 and 614, are biased by PBIA_C and PBIAS_F signals, respectively. These bias signals are generated from associated replica bias circuits 607, 608, which in turn are driven from reference current generator circuit 606 from the current reference generation circuit 605. Note that the fine-tune DAC 614 is also coupled to be biased by the PLL circuit 630 when it is active and when the PLL_En switch is open to disconnect the FLL bias circuitry.

The FSM 620 includes circuit modules to generate the DCO control word (DCW). IN the depicted example, it generates an 11-bit (<10:0> control word that is converted into a 2048-bit thermometer control word by the B2Th encoder 625.

The feedback count circuit 615 is coupled between the DCO 610 and the FSM 620 to provide a digitized frequency feedback from the DCO to the FSM. The count circuit 615 includes buffers 616, parallel coupled counters 617 and an adder 618 to combine the individual counter circuits to provide an aggregate sum count corresponding to a count for the DCO. With the depicted example, the counters 617 are gray code counters.

The FSM 620 includes a target count section 621, a comparator section 622, and a DCW logic 623. The target count section 621 generates a target count value for the comparator based on input reference clock (Fref), ratio, #CNT, and #WIN inputs. The resultant target count is compared at 622 with the aggregated sum count from the feedback count circuit 615. The result is provided as a count error for the DCW logic 623, which generates the DCO control word based on this difference.

The FSM 620, with the DCW logic 623, functions as a frequency detector to cause the DCO to settle to a target frequency (F1) with a corresponding DCO word M. In some embodiments, F1 is equal to an integer multiple N times the reference frequency (Fref). For example, F1 may range from 400 MHz to 7 GHz with: 64≤M≤2047. In some embodiments, the DCW logic may implement a digital proportional-integral (PI) controller to generate the DCO control code. It may also implement a filter to remove high-frequency noise and stabilize the frequency control loop dynamics.

When the hybrid clock generator circuit is in the PLL mode, the PLL_En switch is opened and the PLL section 630 is enabled. The DAC digital control settings from the locked FLL are maintained, but the active control circuitry for the FLL is de-activated, and the PLL effectively takes over active control of the DCO by controlling the bias current for the fine-tune DAC 614. It controls this bias through its analog control loop, e.g., from an output (Vctl) of the PLL

The PLL components 630 include a phase frequency detector (PFD) 632, a charge pump (CP) 634, a low-pass filter (LPF) 636, a ratio divider circuit 638, and a charge pump bias current circuit 640, coupled as shown. The charge pump (CP) 634 receives a bias current (Icp_bias) derived by the CP bias circuit 640 from a virtual supply (VRO) from the DCO. The PLL components may be implemented with any suitable circuits for performing their functions. For example, the loop filter 636 may be implemented with a passive RCC topology as may be known.

In some embodiments, the PLL is implemented using a Type-II charge pump design. The CP bias circuit 640 may be implemented with circuit 640a of FIG. 6B. This bias generation circuit converts the VRO signal to a proportional current (Icp_bias) so that a ratio: Icp/N is near constant. The expression for a second-order Type-II PLL's natural frequency (ωₙ) may be used to approximate the loop bandwidth and inform the PLL design. The approximation is based on the fact that the PLL's-3 dB bandwidth is 2.5 ω when the loop's damping factor is 1, a typical design target. The natural frequency (ωₙ) can be expressed as: ωn=[(Icp*Kvco)/(2πNC1)]½, where Icp is the charge pump current, Kvco is the gain of the Vctl-voltage controlled RO (DCO acting as VCO in PLL mode), and C1 is the loop filter capacitance.

In some embodiments, with Icp being proportional to the Icp_bias signal and thus proportional to Fout, the PLL bandwidth is similar across the operable output clock frequency range. This is because the ratio: Icp/N is near constant. When X (value delineating most significant and least significant bits of the DCW, is much less than M, the VCO gain (Kvco) in PLL mode may be small, which allows for a small C1. This is desirable because it allows for the PLL footprint to consume less circuit area than otherwise would be required.

In operation, a transition from FLL to PLL mode may begin once the FLL settles at its target frequency (F1). For the PLL to become active, the PLL_En switch is opened so that DAC 614 is biased by Vctl instead of PBIAS_F. Next, the PLL's PFD 632 and CP 634 may be enabled, which closes the phase lock loop. The PLL can then fine tune the DCO frequency and phase. In some embodiments, an X/M ratio of less than 10% may be sufficient to avoid running out of the PLL loop's frequency tuning range due to temperature drift, etc.

To handle dynamic frequency transitions without overshoot, the PLL loop may temporarily be disabled with the FLL loop being re-enabled to move to the new target frequency. Once the frequency transition is complete, the FLL loop may then again be disabled and the PLL loop re-enabled.

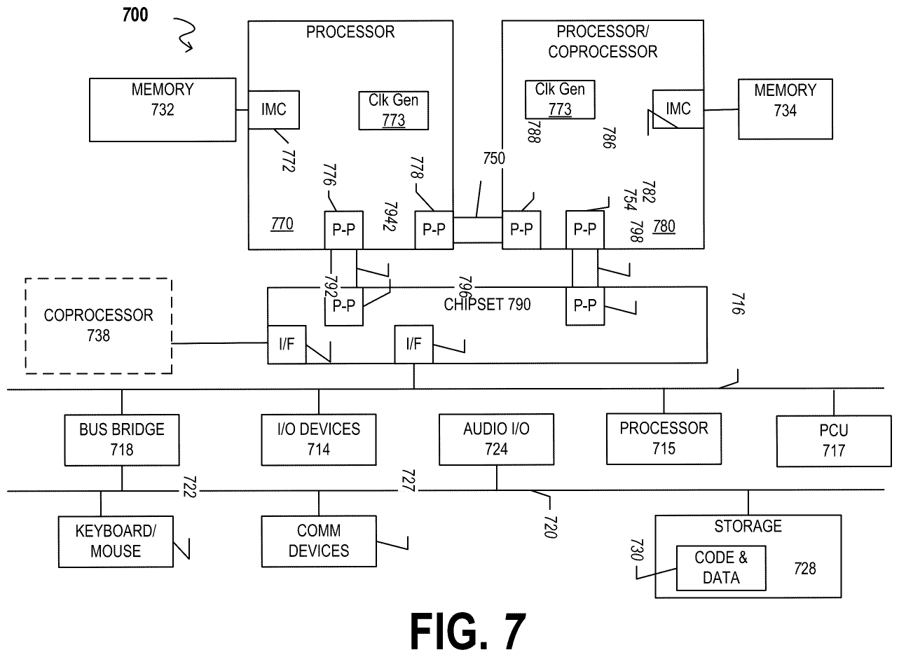

FIG. 7 illustrates an example computing system including at least one clock generation circuit as described herein in accordance with some embodiments. Multiprocessor system 700 is an interfaced system and includes a plurality of processors including a first processor 770 and a second processor 780 coupled via an interface 750 such as a point-to-point (P-P) interconnect, a fabric, and/or bus. In some examples, the first processor 770 and the second processor 780 are homogeneous. In some examples, first processor 770 and the second processor 780 are heterogenous. Though the example multiprocessor system 700 is shown to have two processors, the system may have three or more processors, or may be a single processor system. In some examples, the computing system is implemented, wholly or partially, with a system on a chip (SoC) or a multi-chip (or multi-chiplet) module, in the same or in different package combinations.

Processors 770 and 780 are shown including integrated memory controller (IMC) circuitry 772 and 782, respectively. Processor 770 also includes interface circuits 776 and 778, along with core sets. Similarly, second processor 780 includes interface circuits 786 and 788, along with a core set as well. A core set generally refers to one or more compute cores that may or may not be grouped into different clusters, hierarchal groups, or groups of common core types. Cores may be configured differently for performing different functions and/or instructions at different performance and/or power levels. The processors may also include other blocks such as memory and other processing unit engines.

Processors 770, 780 may exchange information via the interface 750 using interface circuits 778, 788. IMCs 772 and 782 couple the processors 770, 780 to respective memories, namely a memory 732 and a memory 734, which may be portions of main memory locally attached to the respective processors.

Processors 770, 780 may each exchange information with a network interface (NW I/F) 790 via individual interfaces 752, 754 using interface circuits 776, 794, 786, 798. The network interface 790 (e.g., one or more of an interconnect, bus, and/or fabric, and in some examples is a chipset) may optionally exchange information with a co-processor 738 via an interface circuit 792. In some examples, the co-processor 738 is a special-purpose processor, such as, for example, a high-throughput processor, a network or communication processor, compression engine, graphics processor, general purpose graphics processing unit (GPGPU), neural-network processing unit (NPU), embedded processor, or the like.

A shared cache (not shown) may be included in either processor 770, 780 or outside of both processors, yet connected with the processors via an interface such as P-P interconnect, such that either or both processors'local cache information may be stored in the shared cache if a processor is placed into a low power mode.

Network interface 790 may be coupled to a first interface 716 via interface circuit 796. In some examples, first interface 716 may be an interface such as a Peripheral Component Interconnect (PCI) interconnect, a PCI Express interconnect, or another I/O interconnect. In some examples, first interface 716 is coupled to a power control unit (PCU) 717, which may include circuitry, software, and/or firmware to perform power management operations with regard to the processors 770, 780 and/or co-processor 738. PCU 717 provides control information to one or more voltage regulators (not shown) to cause the voltage regulator(s) to generate the appropriate regulated voltage(s). PCU 717 also provides control information to control the operating voltage generated. In various examples, PCU 717 may include a variety of power management logic units (circuitry) to perform hardware-based power management. Such power management may be wholly processor controlled (e.g., by various processor hardware, and which may be triggered by workload and/or power, thermal or other processor constraints) and/or the power management may be performed responsive to external sources (such as a platform or power management source or system software).

PCU 717 is illustrated as being present as logic separate from the processor 770 and/or processor 780. In other cases, PCU 717 may execute on a given one or more of cores (not shown) of processor 770 or 780. In some cases, PCU 717 may be implemented as a microcontroller (dedicated or general-purpose) or other control logic configured to execute its own dedicated power management code, sometimes referred to as P-code. In yet other examples, power management operations to be performed by PCU 717 may be implemented externally to a processor, such as by way of a separate power management integrated circuit (PMIC) or another component external to the processor. In yet other examples, power management operations to be performed by PCU 717 may be implemented within BIOS or other system software. Along these lines, power management may be performed in concert with other power control units implemented autonomously or semi-autonomously, e.g., as controllers or executing software in cores, clusters, IP blocks and/or in other parts of the overall system.

Various I/O devices 714 may be coupled to first interface 716, along with a bus bridge 718 which couples first interface 716 to a second interface 720. In some examples, one or more additional processor(s) 715, such as coprocessors, high throughput many integrated core (MIC) processors, GPGPUs, accelerators (such as graphics accelerators or digital signal processing (DSP) units), field programmable gate arrays (FPGAs), or any other processor, are coupled to first interface 716. In some examples, second interface 720 may be a low pin count (LPC) interface. Various devices may be coupled to second interface 720 including, for example, a keyboard and/or mouse 722, communication devices 727 and storage circuitry 728. Storage circuitry 728 may be one or more non-transitory machine-readable storage media as described below, such as a disk drive or other mass storage device which may include instructions/code and data 730 and may implement the storage in some examples. Further, an audio I/O 724 may be coupled to second interface 720. Note that other architectures than the point-to-point architecture described above are possible. For example, instead of the point-to-point architecture, a system such as multiprocessor system 700 may implement a multi-drop interface or other such architecture.

Processor cores may be implemented in different ways, for different purposes, and in different processors. For instance, implementations of such cores may include: 1) a general purpose in-order core intended for general-purpose computing; 2) a high-performance general purpose out-of-order core intended for general-purpose computing; 3) a special purpose core intended primarily for graphics and/or scientific (throughput) computing. Implementations of different processors may include: 1) a CPU including one or more general purpose in-order cores intended for general-purpose computing and/or one or more general purpose out-of-order cores intended for general-purpose computing; and 2) a coprocessor including one or more special purpose cores intended primarily for graphics and/or scientific (throughput) computing. Such different processors lead to different computer system architectures, which may include: 1) the coprocessor on a separate chip from the CPU; 2) the coprocessor on a separate die in the same package as a CPU; 3) the coprocessor on the same die as a CPU (in which case, such a coprocessor is sometimes referred to as special purpose logic, such as integrated graphics and/or scientific (throughput) logic, or as special purpose cores); and 4) a system on a chip (SoC) that may be included on the same die as the described CPU (sometimes referred to as the application core(s) or application processor(s)), the above described coprocessor, and additional functionality. Example core architectures are described next, followed by descriptions of example processors and computer architectures.

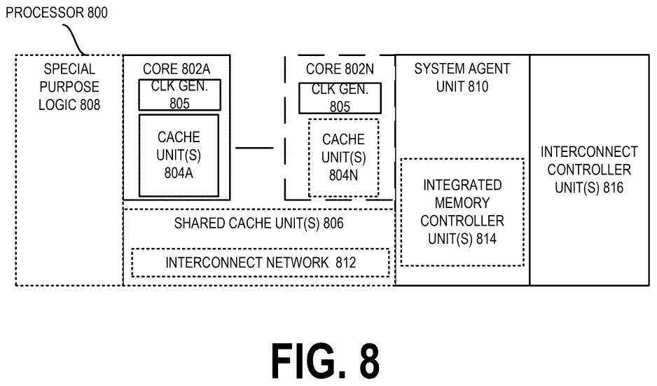

FIG. 8 illustrates a block diagram of an example processor 800 that may have one or more cores and an integrated memory controller in accordance with some embodiments. The solid lined boxes illustrate a processor and/or SoC 800 with a single core 802(A), system agent unit circuitry 810, and a set of one or more interface controller unit(s) circuitry 816, while the optional addition of the dashed lined boxes illustrates an alternative processor and/or SoC 800 with multiple cores 802(A)-(N), a set of one or more integrated memory controller unit(s) circuitry 814 in the system agent unit circuitry 810, and special purpose logic 808, as well as a set of one or more interface controller unit(s) circuitry 816. Note that the processor and/or SoC 800 may be one of the processors 770 or 780, or co-processor 738 or 715 of FIG. 7.

Thus, different implementations of the processor and/or SoC 800 may include: 1) a CPU with the special purpose logic 808 being a high-throughput processor, a network or communication processor, a compression engine, a graphics processor, a general purpose graphics processing unit (GPGPU), a neural-network processing unit (NPU), an embedded processor, a security processor, a matrix accelerator, an in-memory analytics accelerator, a compression accelerator, a data streaming accelerator, data graph operations, or the like(which may include one or more cores, not shown), and the cores 802(A)-(N) being one or more general purpose cores (e.g., general purpose in-order cores, general purpose out-of-order cores, or a combination of the two); 2) a co-processor with the cores 802(A)-(N) being a large number of special purpose cores intended primarily for graphics and/or scientific (throughput); and 3) a co-processor with the cores 802(A)-(N) being a large number of general purpose in-order cores. Thus, the processor and/or SoC 800 may be a general-purpose processor, co-processor or special-purpose processor, such as, for example, a network or communication processor, compression engine, graphics processor, GPGPU (general purpose graphics processing unit), a high throughput many integrated core (MIC) co-processor (including 30 or more cores), embedded processor, or the like. The processor may be implemented on one or more chips. The processor and/or SoC 800 may be a part of and/or may be implemented on one or more substrates using any of a number of process technologies, such as, for example, complementary metal oxide semiconductor (CMOS), bipolar CMOS (BiCMOS), P-type metal oxide semiconductor (PMOS), or N-type metal oxide semiconductor (NMOS).

A memory hierarchy includes one or more levels of cache unit(s) circuitry 804(A)-(N) within the cores 802(A)-(N), a set of one or more shared cache unit(s) circuitry 806, and external memory (not shown) coupled to the set of integrated memory controller unit(s) circuitry 814. The set of one or more shared cache unit(s) circuitry 806 may include one or more mid-level caches, such as level 2 (L2), level 3 (L3), level 4 (L4), or other levels of cache, such as a last level cache (LLC), and/or combinations thereof. While in some examples interface network circuitry 812 (e.g., a ring interconnect) interfaces the special purpose logic 808 (e.g., integrated graphics logic), the set of shared cache unit(s) circuitry 806, and the system agent unit circuitry 810, alternative examples use any number of well-known techniques for interfacing such units. In some examples, coherency is maintained between one or more of the shared cache unit(s) circuitry 806 and cores 802(A)-(N). In some examples, interface controller unit(s) circuitry 816 couple the cores 802(A)-(N) to one or more other devices 818 such as one or more I/O devices, storage, one or more communication devices (e.g., wireless networking, wired networking, etc.), etc.

In some examples, one or more of the cores 802(A)-(N) are capable of multi-threading. The system agent unit circuitry 810 includes those components coordinating and operating cores 802(A)-(N). The system agent unit circuitry 810 may include, for example, power control unit (PCU) circuitry and/or display unit circuitry (not shown). The PCU may be or may include logic and components needed for regulating the power state of the cores 802(A)-(N) and/or the special purpose logic 808 (e.g., integrated graphics logic). The display unit circuitry is for driving one or more externally connected displays.

The cores 802(A)-(N) may be homogenous in terms of instruction set architecture (ISA). Alternatively, the cores 802(A)-(N) may be heterogeneous in terms of ISA; that is, a subset of the cores 802(A)-(N) may be capable of executing an ISA, while other cores may be capable of executing only a subset of that ISA or another ISA.

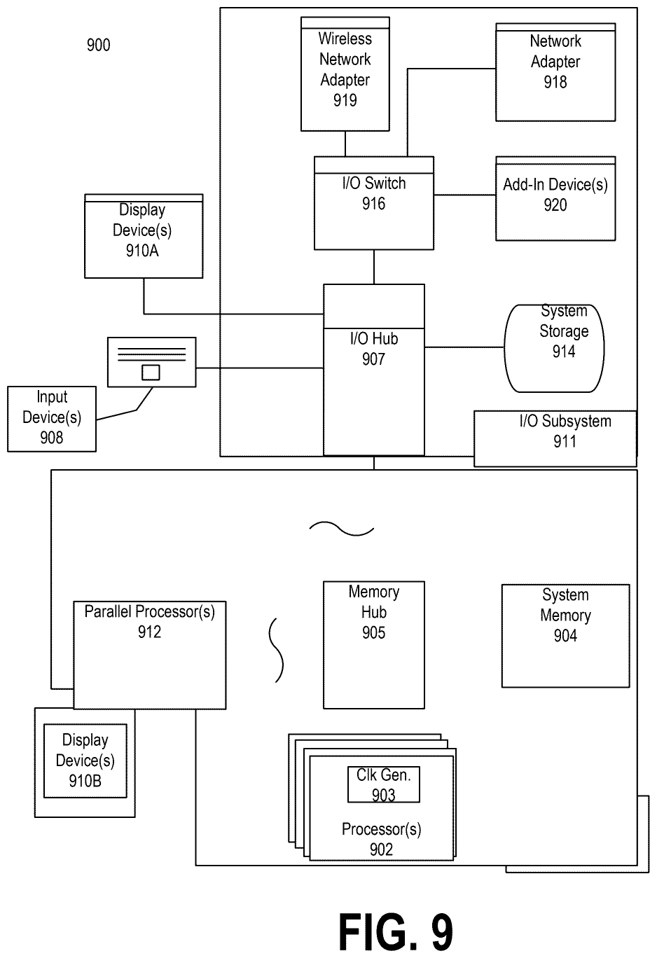

FIG. 9 is a block diagram illustrating a parallel processing computing system 900 configured to implement one or more aspects of the examples described herein. The computing system 900 includes a processing subsystem 901 having one or more processor(s) 902 and a system memory 904 communicating via an interconnection path that may include a memory hub 905. The memory hub 905 may be a separate component within a chipset component or may be integrated within the one or more processor(s) 902. The memory hub 905 couples with an I/O subsystem 911 via a communication link 906. The I/O subsystem 911 includes an I/O hub 907 that can enable the computing system 900 to receive input from one or more input device(s) 908. Additionally, the I/O hub 907 can enable a display controller, which may be included in the one or more processor(s) 902, to provide outputs to one or more display device(s) 910A. In some examples the one or more display device(s) 910A coupled with the I/O hub 907 can include a local, internal, or embedded display device.

The processing subsystem 901, for example, includes one or more parallel processor(s) 912 coupled to memory hub 905 via a bus or communication link 913. The communication link 913 may be one of any number of standards-based communication link technologies or protocols, such as, but not limited to PCI Express, or may be a vendor specific communications interface or communications fabric. The one or more parallel processor(s) 912 may form a computationally focused parallel or vector processing system that can include a large number of processing cores and/or processing clusters, such as a many integrated core (MIC) processor. For example, the one or more parallel processor(s) 912 form a graphics processing subsystem that can output pixels to one of the one or more display device(s) 910A coupled via the I/O hub 907. The one or more parallel processor(s) 912 can also include a display controller and display interface (not shown) to enable a direct connection to one or more display device(s) 910B.

Within the I/O subsystem 911, a system storage unit 914 can connect to the I/O hub 907 to provide a storage mechanism for the computing system 900. An I/O switch 916 can be used to provide an interface mechanism to enable connections between the I/O hub 907 and other components, such as a network adapter 918 and/or wireless network adapter 919 that may be integrated into the platform, and various other devices that can be added via one or more add-in device(s) 920. The add-in device(s) 920 may also include, for example, one or more external graphics processor devices, graphics cards, and/or compute accelerators. The network adapter 918 can be an Ethernet adapter or another wired network adapter. The wireless network adapter 919 can include one or more of a Wi-Fi, Bluetooth, near field communication (NFC), or other network device that includes one or more wireless radios.

The computing system 900 can include other components not explicitly shown, including USB or other port connections, optical storage drives, video capture devices, and the like, which may also be connected to the I/O hub 907. Communication paths interconnecting the various components in FIG. 9 may be implemented using any suitable protocols, such as PCI (Peripheral Component Interconnect) based protocols (e.g., PCI-Express), or any other bus or point-to-point communication interfaces and/or protocol(s), such as the NVLink high-speed interconnect, Compute Express Link™ (CXL™) (e.g., CXL. mem), Infinity Fabric (IF), Ethernet (IEEE 802.3), remote direct memory access (RDMA), InfiniBand, Internet Wide Area RDMA Protocol (iWARP), Transmission Control Protocol (TCP), User Datagram Protocol (UDP), quick UDP Internet Connections (QUIC), RDMA over Converged Ethernet (RoCE), Intel QuickPath Interconnect (QPI), Intel Ultra Path Interconnect (UPI), Intel On-Chip System Fabric (IOSF), Omnipath, HyperTransport, Advanced Microcontroller Bus Architecture (AMBA) interconnect, OpenCAPI, Gen-Z, Cache Coherent Interconnect for Accelerators (CCIX), 3GPP Long Term Evolution (LTE) (4G), 3GPP 5G, and variations thereof, or wired or wireless interconnect protocols known in the art. In some examples, data can be copied or stored to virtualized storage nodes using a protocol such as non-volatile memory express (NVMe) over Fabrics (NVMe-oF) or NVMe.

The one or more parallel processor(s) 912 may incorporate circuitry optimized for graphics and video processing, including, for example, video output circuitry, and constitutes a graphics processing unit (GPU). Alternatively or additionally, the one or more parallel processor(s) 912 can incorporate circuitry optimized for general purpose processing, while preserving the underlying computational architecture, described in greater detail herein. Components of the computing system 900 may be integrated with one or more other system elements on a single integrated circuit. For example, the one or more parallel processor(s) 912, memory hub 905, processor(s) 902, and I/O hub 907 can be integrated into a system on chip (SoC) integrated circuit. Alternatively, the components of the computing system 900 can be integrated into a single package to form a system in package (SIP) configuration. In some examples at least a portion of the components of the computing system 900 can be integrated into a multi-chip module (MCM), which can be interconnected with other multi-chip modules into a modular computing system.

It will be appreciated that the computing system 900 shown herein is illustrative and that variations and modifications are possible. The connection topology, including the number and arrangement of bridges, the number of processor(s) 902, and the number of parallel processor(s) 912, may be modified as desired. For instance, system memory 904 can be connected to the processor(s) 902 directly rather than through a bridge, while other devices communicate with system memory 904 via the memory hub 905 and the processor(s) 902. In other alternative topologies, the parallel processor(s) 912 are connected to the I/O hub 907 or directly to one of the one or more processor(s) 902, rather than to the memory hub 905. In other examples, the I/O hub 907 and memory hub 905 may be integrated into a single chip. It is also possible that two or more sets of processor(s) 902 are attached via multiple sockets, which can couple with two or more instances of the parallel processor(s) 912.

Some of the particular components shown herein are optional and may not be included in all implementations of the computing system 900. For example, any number of add-in cards or peripherals may be supported, or some components may be eliminated. Furthermore, some architectures may use different terminology for components similar to those illustrated in FIG. 9. For example, the memory hub 905 may be referred to as a Northbridge in some architectures, while the I/O hub 907 may be referred to as a Southbridge.

### Example Embodiments

Illustrative examples of the technologies disclosed herein are provided below. An embodiment of the technologies may include any one or more, and any compatible combination of, the examples described below.

Example 1 is an apparatus that includes a phase lock loop circuit and a ratio control circuit. The ratio control circuit is coupled to the PLL circuit. The ratio control circuit includes a logic circuit to control a size of a next ratio upward step based on a ratio error that corresponds to a difference between a current ratio and a target ratio.

Example 2 includes the subject matter of example 1, and wherein the logic circuit is coupled to the PLL circuit to receive a phase error, the logic circuit to control when the next ratio upward step is to occur based on the phase error.

Example 3 includes the subject matter of any of examples 1-2, and wherein the logic circuit includes a time-to-digital converter to receive the phase error from the PLL circuit and to generate from it a phase error code to use for controlling when the next ratio upward step is to occur.

Example 4 includes the subject matter of any of examples 1-3, and wherein the logic circuit is to generate a phase error tolerance based on the ratio error and control the next ratio upward step to occur responsive to the phase error being within the phase error tolerance.

Example 5 includes the subject matter of any of examples 1-4, and wherein the phase error tolerance corresponds to the ratio error.

Example 6 includes the subject matter of any of examples 1-5, and wherein the phase error tolerance logarithmically corresponds to the ratio error.

Example 7 includes the subject matter of any of examples 1-6, and wherein the PLL circuit includes a frequency control input node coupled to the ratio control circuit to receive a frequency control word that corresponds to the next ratio.

Example 8 includes the subject matter of any of examples 1-7, and wherein the ratio control circuit includes a clock input node coupled to a feedback path of the PLL circuit.

Example 9 includes the subject matter of any of examples 1-8, and wherein the logic circuit includes a ratio error detector circuit to provide the ratio error and a step release circuit to control when the next ratio upward step is to occur.

Example 10 includes the subject matter of any of examples 1-9, and wherein the logic circuit includes a ratio selection circuit coupled to the step release circuit, wherein the ratio selection circuit is to convey a selected one of the next ratio upward step or the target ratio to the PLL circuit in response to a signal from the step release circuit.

Example 11 includes the subject matter of any of examples 1-10, and comprising a processor with a clock generator circuit including the PLL circuit and ratio control circuit.

Example 12 is an apparatus that includes a frequency lock loop (FLL) circuit and phase lock loop (PLL) components. The FLL includes a controllable oscillator with a clock output node. The PLL components are coupled to the controllable oscillator, and the controllable oscillator is controlled (i) by the PLL components to form a PLL that includes the controllable oscillator with the FLL being inactive in a first operational mode, and (ii) by the FLL with the PLL being inactive in a second operational mode.

Example 13 includes the subject matter of example 12, and comprising a digital to analog converter (DAC) circuit coupled to control the controllable oscillator, wherein the DAC circuit includes a digital selection input to select a portion of the DAC circuit to be active and a bias input to control a strength of the selected portion.

Example 14 includes the subject matter of any of examples 12-13, and wherein the bias input is coupled to a first bias source through a switch, the first bias source being part of the FLL.

Example 15 includes the subject matter of any of examples 12-14, and wherein the bias input is coupled to a second bias source that is part of the PLL components.

Example 16 includes the subject matter of any of examples 12-15, and wherein the DAC circuit is a first DAC circuit, the apparatus including a second DAC circuit coupled with the first DAC circuit to drive the controllable oscillator with the first DAC circuit providing fine-tune adjustment, and the second DAC circuit providing course-tune adjustment.

Example 17 includes the subject matter of any of examples 12-16, and wherein the digital selection input of the first DAC circuit is a first digital selection input and the bias input of the first DAC circuit is a first bias input, the second DAC circuit including a second digital selection input and a second bias input, the first digital selection input corresponding to least significant bits of a digital control word for controlling the oscillator, and the second digital selection input corresponding to most significant bits of the digital control word.

Example 18 includes the subject matter of any of examples 12-17, and wherein the PLL components include a charge pump coupled to a charge pump bias source with a control input that is coupled to a virtual supply node of the controllable oscillator.

Example 19 includes the subject matter of any of examples 12-18, and comprising a processor with a clock generator circuit including the PLL circuit and ratio control circuit.

Example 20 is a processor apparatus a processing core, a PLL, and a frequency control circuit. The phase lock loop (PLL) circuit is coupled to the processing core to provide a clock with a clock frequency. The PLL circuit includes a feedback path with a fractional divider circuit to control the clock frequency. The frequency control circuit is coupled to the fractional divider circuit. The frequency control circuit is to control a step size of a transition from a current clock frequency to a higher, target clock frequency. The step size is controlled to correspond to a frequency distance between the current and target clock frequencies.

Example 21 includes the subject matter of example 20, and wherein the frequency control circuit is to control when the transition occurs based on a phase error of the PLL circuit.

Example 22 includes the subject matter of any of examples 20-21, and wherein the frequency control circuit includes a time-to-digital converter coupled to the PLL circuit to receive the phase error and to generate from it a phase error code, wherein the TDC has a clock input coupled to the feedback path to receive a feedback clock.

Example 23 includes the subject matter of any of examples 20-22, and wherein the logic circuit is to generate a phase error tolerance based on the frequency distance and is to control when the transition is to occur responsive to the phase error code being within the phase error tolerance.

Example 24 includes the subject matter of any of examples 20-23, and wherein the phase error tolerance logarithmically corresponds to the frequency distance.

Example 25 includes the subject matter of any of examples 20-24, and comprising a quantization error correction circuit coupled to the feedback path.

Example 26 includes the subject matter of any of examples 20-25, and comprising a power management control circuit coupled to the frequency control circuit to set the target frequency as part of a dynamic voltage frequency scaling feature.

Example 27 includes the subject matter of any of examples 20-26, and wherein the frequency transition is to occur while the PLL remains active.

Reference in the specification to “an embodiment,” “one embodiment,” “some embodiments,” or “other embodiments” means that a particular feature, structure, or characteristic described in connection with the embodiments is included in at least some embodiments, but not necessarily all embodiments. The various appearances of “an embodiment,” “one embodiment,” or “some embodiments” are not necessarily all referring to the same embodiments. If the specification states a component, feature, structure, or characteristic “may,” “might,” or “could” be included, that particular component, feature, structure, or characteristic is not required to be included.

Throughout the specification, and in the claims, the term “connected” means a direct connection, such as electrical, mechanical, or magnetic connection between the things that are connected, without any intermediary devices.

The term “coupled” means a direct or indirect connection, such as a direct electrical, mechanical, or magnetic connection between the things that are connected or an indirect connection, through one or more passive or active intermediary devices.

The term “circuit” or “module” may refer to one or more passive and/or active components that are arranged to cooperate with one another to provide a desired function. It should be appreciated that different circuits or modules may consist of separate components, they may include both distinct and shared components, or they may consist of the same components. For example, A controller circuit may be a first circuit for performing a first function, and at the same time, it may be a second controller circuit for performing a second function, related or not related to the first function.

The meaning of “in” includes “in” and “on” unless expressly distinguished for a specific description.

The terms “substantially,” “close,” “approximately,” “near,” and “about,” unless otherwise indicated, generally refer to being within +/−10% of a target value.

Unless otherwise specified, the use of the ordinal adjectives “first,” “second,” and “third,” etc., to describe a common object, merely indicate that different instances of like objects are being referred to and are not intended to imply that the objects so described must be in a given sequence, either temporally, spatially, in ranking or in any other manner

For the purposes of the present disclosure, phrases “A and/or B” and “A or B” mean (A), (B), or (A and B). For the purposes of the present disclosure, the phrase “A, B, and/or C” means (A), (B), (C), (A and B), (A and C), (B and C), or (A, B and C).

It is pointed out that those elements of the figures having the same reference numbers (or names) as the elements of any other figure can operate or function in any manner similar to that described but are not limited to such.

For purposes of the embodiments, unless expressly described differently, the transistors in various circuits and logic blocks described herein may be implemented with any suitable transistor type such as field effect transistors (FETs) or bipolar type transistors. FET transistor types may include but are not limited to metal oxide semiconductor (MOS) type FETs such as tri-gate, FinFET, and gate all around (GAA) FET transistors, as well as tunneling FET (TFET) transistors, ferroelectric FET (FeFET) transistors.

In the drawings of the embodiments, signals are represented with lines. Some lines may appear different from others, for example, thicker or hatched, to distinguish from other depicted signals for ease of understanding. Along these lines, some signal lines may have arrows at one or more ends, to indicate a primary direction of information flow. However, such indications are not intended to be limiting. Rather, lines are used in connection with one or more exemplary embodiments in a given figure to facilitate easier understanding of concepts embodied in block, circuit, and/or flow diagrams. Any represented signal, as dictated by design needs or preferences, may actually comprise one or more signals that may travel in either direction and may be implemented with any suitable type of signal scheme, e.g., analog, digital, wired, wireless, upon the platform within which the present disclosure is to be implemented.

As defined herein, the term “computer readable storage medium” means a storage medium that contains or stores program code for use by or in connection with an instruction execution system, apparatus, or device. As defined herein, a “computer readable storage medium” is not a transitory, propagating signal per se. A computer readable storage medium may be, but is not limited to, an electronic storage device, a magnetic storage device, an optical storage device, an electromagnetic storage device, a semiconductor storage device, or any suitable combination of the foregoing. Memory elements, as described herein, are examples of a computer readable storage medium.

As defined herein, the term “processor” means at least one hardware circuit configured to carry out instructions contained in program code. The hardware circuit may be implemented with one or more integrated circuits. Examples of a processor include, but are not limited to, a central processing unit (CPU), an array processor, a vector processor, a digital signal processor (DSP), a field-programmable gate array (FPGA), a programmable logic array (PLA), an application specific integrated circuit (ASIC), programmable logic circuitry, a graphics processing unit (GPU), a controller, and so forth. It should be appreciated that a logical processor, on the other hand, is a processing abstraction associated with a core, for example when one or more SMT cores are being used such that multiple logical processors may be associated with a given core, for example, in the context of core thread assignment.

It should be appreciated that a processor or processor system may be implemented in various different manners. For example, they may be implemented on a single die, multiple dies (dielets, chiplets), one or more dies in a common package, or one or more dies in multiple packages. Along these lines, some of these blocks may be located separately on different dies or together on two or more different dies.

While the flow diagrams in the figures show a particular order of operations performed by certain embodiments of the invention, it should be understood that such order is exemplary (e.g., alternative embodiments may perform the operations in a different order, combine certain operations, overlap certain operations, etc.).

While the invention has been described in terms of several embodiments, those skilled in the art will recognize that the invention is not limited to the embodiments described, can be practiced with modification and alteration within the spirit and scope of the appended claims. The description is thus to be regarded as illustrative instead of limiting.

What is claimed is:

1. An apparatus, comprising:
a phase lock loop (PLL) circuit; and
a ratio control circuit coupled to the PLL circuit, the ratio control circuit to control a size of a next ratio upward step based on a ratio error that corresponds to a difference between a current ratio and a target ratio.

2. The apparatus of claim 1, wherein the ratio control circuit is coupled to the PLL circuit to receive a phase error, the ratio control circuit to control when the next ratio upward step is to occur based on the phase error.

3. The apparatus of claim 2, wherein the ratio control circuit includes a time-to-digital converter to receive the phase error from the PLL circuit and to generate from it a phase error code to use for controlling when the next ratio upward step is to occur.

4. The apparatus of claim 2, wherein the ratio control circuit is to generate a phase error tolerance based on the ratio error and control the next ratio upward step to occur responsive to the phase error being within the phase error tolerance.

5. The apparatus of claim 4, wherein the phase error tolerance corresponds to the ratio error.

6. The apparatus of claim 5, wherein the phase error tolerance logarithmically corresponds to the ratio error.

7. The apparatus of claim 1, wherein the PLL circuit includes a frequency control input node coupled to the ratio control circuit to receive a frequency control word that corresponds to the next ratio.

8. The apparatus of claim 1, wherein the ratio control circuit includes a clock input node coupled to a feedback path of the PLL circuit.

9. The apparatus of claim 1, wherein the ratio control circuit includes a ratio error detector circuit to provide the ratio error and a step release circuit to control when the next ratio upward step is to occur.

10. The apparatus of claim 9, wherein the ratio control circuit includes a ratio selection circuit coupled to the step release circuit, wherein the ratio selection circuit is to convey a selected one of the next ratio upward step or the target ratio to the PLL circuit in response to a signal from the step release circuit.

11. The apparatus of claim 1, comprising a processor with a clock generator circuit including the PLL circuit and ratio control circuit.

12. An apparatus, comprising:
a frequency locked loop (FLL) circuit including a controllable oscillator with a clock output node; and
phase locked loop (PLL) circuitry coupled to the controllable oscillator, the controllable oscillator controlled (i) by the PLL circuitry to form a PLL that includes the controllable oscillator with the FLL being inactive in a first operational mode, and (ii) by the FLL with the PLL being inactive in a second operational mode.

13. The apparatus of claim 12, comprising a digital to analog converter (DAC) circuit coupled to control the controllable oscillator, wherein the DAC circuit includes a digital selection input to select a portion of the DAC circuit to activate and a bias input to control a strength of the selected portion.

14. The apparatus of claim 13, wherein the bias input is coupled to a first bias source through a switch, the first bias source being part of the FLL.

15. The apparatus of claim 14, wherein the bias input is coupled to a second bias source that is part of the PLL circuitry.

16. The apparatus of claim 13, wherein the DAC circuit is a first DAC circuit, the apparatus further comprising a second DAC circuit coupled with the first DAC circuit to drive the controllable oscillator with the first DAC circuit providing fine-tune adjustment, and the second DAC circuit providing course-tune adjustment.

17. The apparatus of claim 16, wherein the digital selection input of the first DAC circuit is a first digital selection input and the bias input of the first DAC circuit is a first bias input, the second DAC circuit including a second digital selection input and a second bias input, the first digital selection input corresponding to least significant bits of a digital control word for controlling the oscillator, and the second digital selection input corresponding to most significant bits of the digital control word.

18. The apparatus of claim 12, wherein the PLL circuitry includes a charge pump coupled to a charge pump bias source with a control input that is coupled to a virtual supply node of the controllable oscillator.

19. A processor apparatus, comprising:
a processing core;
a phase lock loop (PLL) circuit coupled to the processing core to provide a clock with a clock frequency, the PLL circuit including a feedback path with a fractional divider circuit to control the clock frequency; and
a frequency control circuit coupled to the fractional divider circuit, the frequency control circuit to control a step size of a transition from a current clock frequency to a higher, target clock frequency, wherein the step size is controlled to correspond to a frequency distance between the current and target clock frequencies.

20. The apparatus of claim 19, wherein the frequency control circuit controls when the transition occurs based on a phase error of the PLL circuit.
